(19) United States
(12) Patent Application Publication
(10) Pub. No.: US 2024/0113009 A1
(43) Pub. Date: Apr. 4, 2024

(54) POROUS POLYMER DIELECTRIC LAYER ON CORE

(71) Applicant: Intel Corporation, Santa Clara, CA (US)

(72) Inventors: Whitney Bryks, Tempe, AZ (US); Aaditya Candadai, Chandler, AZ (US); Dilan Seneviratne, Phoenix, AZ (US); Junxin Wang, Gilbert, AZ (US); Peumie Abeyratne Kuragama, Chandler, AZ (US)

(73) Assignee: Intel Corporation, Santa Clara, CA (US)

(21) Appl. No.: 17/957,637

(22) Filed: Sep. 30, 2022

(51) Int. Cl. H01L 23/498; B05D 3/02; B05D 3/04; B05D 5/00; H01L 21/48; H01L 23/14; H01L 23/15; H01L 23/538

(52) U.S. Cl. CPC H01L 23/49894; B05D 3/0272; B05D 3/0426; B05D 5/00; H01L 21/481; H01L 23/147; H01L 23/15; H01L 23/5383; H01L 23/5384

(57) ABSTRACT

An electronic device can include an interposer, a first porous polymer layer, and one or more die. The interposer can include a metallic through via extending from a first surface of the interposer to a second surface of the interposer. The first polymer layer can be adjacent to the first surface of the interposer. The one or more dies can be coupled to the first porous polymer layer and connected to the metallic through via.

### TECHNICAL FIELD

Embodiments described herein generally relate to electronic devices. More specifically, embodiments described herein relate to electronic devices that include a porous polymer dielectric layer on a core and method.

### BACKGROUND

New signaling standards are expected to cause high electrical losses resulting in electrical waste and signal quality. For example, new signaling applications such as PCIe Gen 6, or any other signaling application, can result in electrical waste and signal quality degradation. It is desired to have electronic devices that address these concerns and other technical challenges.

### BRIEF DESCRIPTION OF THE DRAWINGS

FIG. 1 shows an example of an electronic device with a porous polymer dielectric layer on a core.

FIG. 2 shows another example of an electronic device with a porous polymer dielectric layer on a core.

FIG. 3 shows an example of a computing device with an electronic device including a porous polymer dielectric layer on a core.

FIG. 4 shows a flow diagram of a method of manufacture of an example of an electronic device with a porous polymer dielectric layer on a core.

FIG. 5 shows a flow diagram of another method of manufacture of an example of an electronic device with a porous polymer dielectric layer on a core.

FIG. 6 shows a flow diagram of yet another method of manufacture of an example of an electronic device with a porous polymer dielectric layer on a core.

FIG. 7 shows a system that may incorporate a computing device with an electronic device with a porous polymer dielectric layer on a core and methods.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present disclosure relates to an electronic device including a porous polymer dielectric layer on a core. In examples, the core can be glass or silicon. The glass or silicon cores provide good electrical properties while enabling thermal processing of the porous polymer dielectric layer at high temperatures for good adhesion. The porous polymer dielectric can prevent electrical waste and signal degradation with even the highest frequency signaling applications, such as PCIe Gen 6.

The above discussion is intended to provide an overview of subject matter of the present patent application. It is not intended to provide an exclusive or exhaustive explanation of the invention. The description below is included to provide further information about the present patent application.

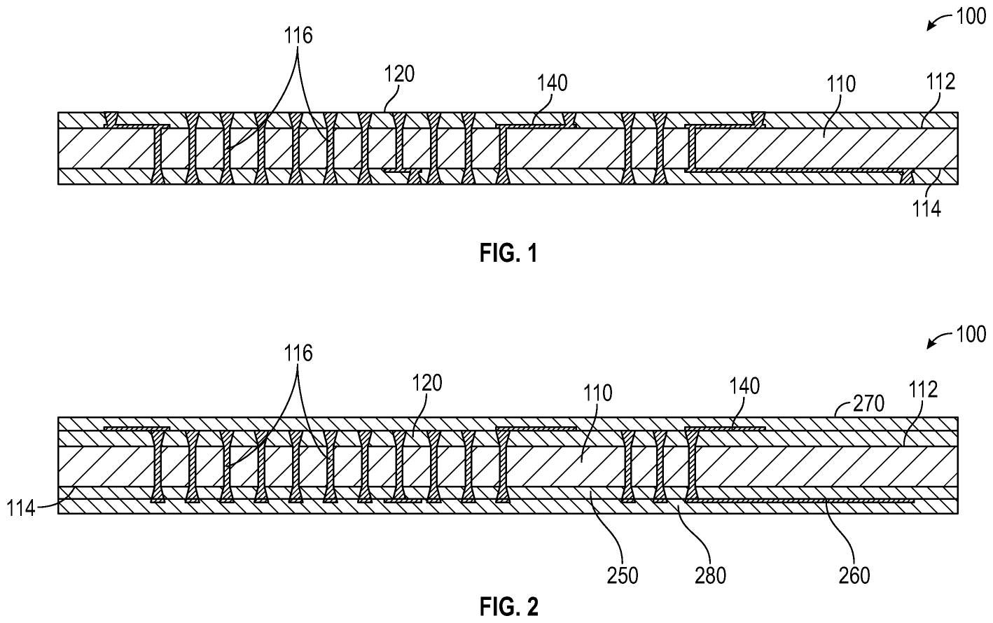

FIG. 1 shows an example of an electronic device 100. The electronic device can include a substrate or interposer (interposer 110), and a first porous polymer layer 120. The interposer 110 can include a first major surface (first surface 112), a second major surface (second surface 114), and a metallic through via 116. The metallic through via 116 can extend from the first surface 112 to the second surface 114. The electronic device 100 can also include one or more horizontal routings 140.

The interposer 110 can be configured to mount to a subsequent circuit board. The interposer 110 can be a glass substrate. One example of a glass substrate can include silicon dioxide glass. Another example of a glass substrate can include a doped silicon dioxide glass. Yet another example of a glass substrate can include quartz. The interposer 110 can also be made of silicon. In yet another example, the interposer 110 can be a ceramic, metallic, or any combination of materials that can be used for high-temperature computing, and the like.

The metallic through via 116 can enable electronic communication through the interposer 110. For example, the metallic through via 116 can be configured to enable electronic communication from a die or other component mounted to the first surface 112 of the interposer 110 to another die or component mounted to the second surface 114 of the interposer 110. The metallic through via 116 can be made from copper, aluminum, stainless steel, or any alloy or combination of materials with electrical conductivity, or the like.

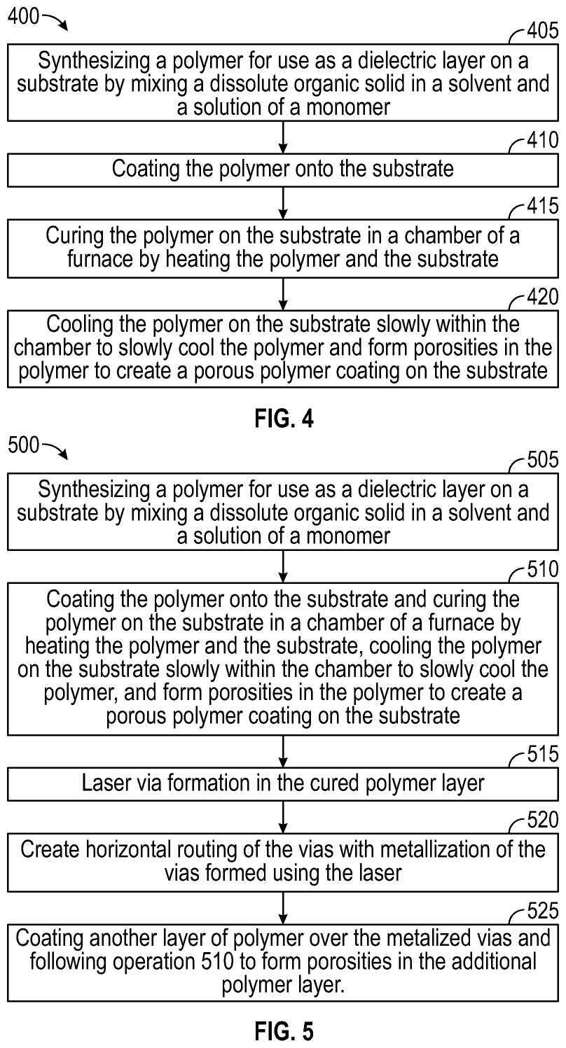

The first porous polymer layer 120 can be adjacent to the first surface 112 of the interposer 110. In examples, the first porous polymer layer 120 can include a nanopolymer. In examples, a nanopolymer can be a polymer that includes nanoparticles. Here, nanoparticles can be in the scale of 1×10⁻⁹ meters. In other examples, the polymers can include particles that are not in the nanoscale. Here, the polymers can be micropolymers, or any other scale polymer, and the like. For example, the first porous polymer layer 120 can be based on porous precursor nanoemulsions that can be prepared from different polymer systems in a porous form with ultralow dielectric constants. For example, the porous polymer can be fluorinated polyimide/POSS, POSS/polyamide, sandwich-type polyimide film, polyethylene/silica, fluorinated polyimide nanocomposite, electrospun epoxy film, polypolyarylene ether nitrile, silicon dioxide, porous polyimide films, polysilsesquioxane, porous cyanoethyl cellulose, nanoporous poly (methyl silsesquioxances), silica/polyimide nanofiber membranes, polyimide aerogel, polyarylene ether nitrile foams, any other polymer with ultralow dielectric constants, any combination of any of these materials, or the like. The processing of the first porous polymer layer 120 will be discussed with reference to FIGS. 4-6 below.

The horizontal routings 140 can enable electrical communication between two dies or subcomponents connected to the electronic device 100. For example, the horizontal routings 140 can electrically connect two dies adjacently mounted to the first surface 112 of the interposer 110. In another example, the horizontal routings 140 can electrically connect two dies adjacently mounted to the second surface 114 of the interposer 110. In an example, the horizontal routings 140 can be interproximal the first surface 112 of the interposer 110 and the first porous polymer layer 120.

FIG. 2 shows another example of the electronic device 100. As shown in FIG. 2, the electronic device 100 can include a second porous polymer layer 250 and one or more second horizontal routings (second horizontal routings 260). The electronic device 100 can also include a third porous polymer layer 270, and a fourth porous polymer layer 280. The second porous polymer layer 250 can be adjacent the second surface 114 of the interposer 110. The third porous polymer layer 270 can be adjacent the first porous polymer layer 120. The fourth porous polymer layer 280 can be adjacent the second porous polymer layer 250.

The second horizontal routings 260 can be interproximal the second surface 114 of the interposer 110 and the second porous polymer layer 250. In another example, the second horizontal routings 260 can be interproximal the first porous polymer layer 120 and the third porous polymer layer 270. In yet another example, the horizontal routings 140 can be interproximal the first porous polymer layer 120 and the third porous polymer layer 270, and the second horizontal routings 260 can be interproximal to the second porous polymer layer 250 and the fourth porous polymer layer 280. The exact configuration of the horizontal routings (e.g., the horizontal routings 140 and the second horizontal routings 260) can be altered as needed for the computing capabilities required of the electronic device 100.

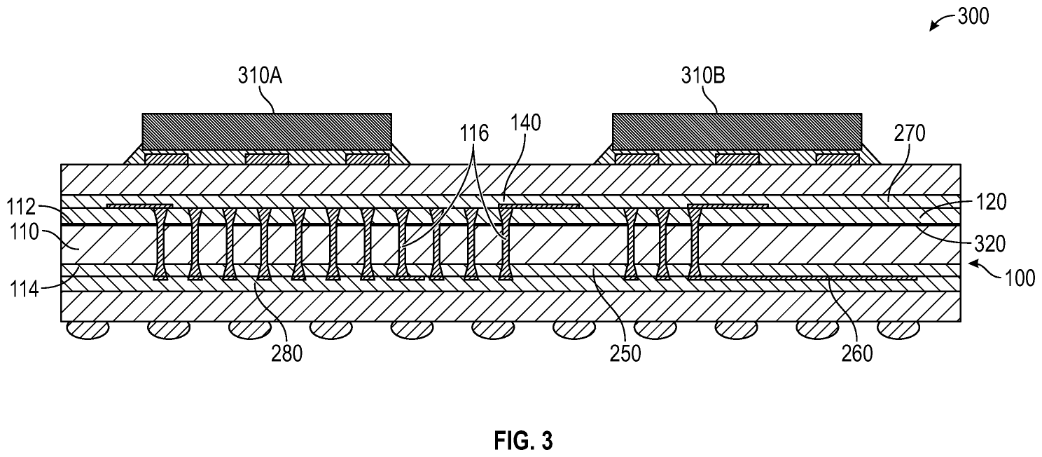

FIG. 3 shows an example of a computing device 300. The computing device 300 can include an electronic device (e.g., the electronic device 100) and one or more dies (dies 310) mounted to the electronic device. In examples, the computing device 300 can be a primary processor for a controller. In another example, the computing device 300 can be a component of a controller.

The dies 310 can be coupled to the first porous polymer layer 120 and electronically connected to the metallic through via 116. A first die 310A can be connected to a second die 310B via horizontal routings (e.g., the horizontal routings 140 or the second horizontal routings 260).

As shown in FIG. 3, the electronic device 100 can include an adhesion promotion layer 320. The adhesion promotion layer 320 can be slit coated or laminated to improve the adhesion of the polymer layers (e.g., the first porous polymer layer 120 or the second porous polymer layer 250) and the interposer 110. For example, the adhesion promotion layer 320 can include a maleimide-based polymer that can have good adhesion to copper due to electron rich nitrogen and oxygen atoms. In examples, oxygen-rich groups (e.g., diketo/keto or ester groups) can further enhance the adhesion of maleimide to copper without changing the dielectric loss. In yet another example, ester groups can be incorporated into the polymer layers through an epoxy-based resin in low quantity to enhance the adhesion between the polymer layers and the adhesion promotion layer 320. The adhesion promotion layer 320 can also improve adhesion between the porous polymer layers and the horizontal routings (e.g., the horizontal routings 140 or the second horizontal routings 260) and the metallic through vias (e.g., the metallic through vias 116).

Methods resulting in such porous layers on glass or silicon substrates will be discussed with reference to FIGS. 4-6 below.

FIG. 4 illustrates a schematic view of the method 400, in accordance with at least one example of this disclosure. The method 400 can be a method of manufacturing an electronic device including a porous polymer dielectric layer on a core. More specific examples of the method 400 are discussed below. The steps or operations of the method 400 are illustrated in a particular order for convenience and clarity; many of the discussed operations can be performed in a different sequence or in parallel without materially impacting other operations. The method 400 as discussed includes operations performed by multiple different actors, devices, and/or systems. It is understood that subsets of the operations discussed in the method 400 can be attributable to a single actor, device, or system could be considered a separate standalone process or method.

At operation 405, the method 400 can include synthesizing a polymer for use as a dielectric layer on a substrate by mixing a dissolute organic solid in a solvent and a solution of a monomer. A general method of synthesizing a porous polymer thin film for use as substrate dielectric layers (e.g., the first porous polymer layer 120, the second porous polymer layer 250, the third porous polymer layer 270, or the fourth porous polymer layer 280) can be by the dissolution of an organic solid in an appropriate solvent mixed in a solution of the desired monomers.

At operation 410, the method 400 can include coating the polymer onto the substrate. The polymer can be coated using slit coating or spin coating on the interposer. In examples, the polymer can be coated onto horizontal routings on the interposer (e.g., the interposer 110).

At operation 415, the method 400 can include curing the polymer on the substrate in a chamber of a furnace by heating the polymer and the substrate. In examples, the polymer on the substrate can be cured in a furnace at three hundred and ninety degrees Celsius for five minutes. The polymer and the substrate can be cured at any other temperature that will cure and adhere the polymer on the substrate. For example, the polymer on the substrate can be cured between three hundred and sixty and four hundred degrees Celsius.

At operation 420, the method 400 can include cooling the polymer on the substrate within the chamber. The polymerization of monomers and evaporation of the organic solvent results in the formation of nanopores in the film. The pores produced using such methods are typically on the order of a few nanometers, so this is considered low risk for reliability concerns associated with wet substrate processing steps. For example, the slow cooling of the polymer layer and the substrate can be tunable to alter the porosities in the polymer layers. For example, the faster the cooling, the smaller the pore sizes in the polymer, and the slower the cooling the larger the pore sizes in the polymer layer.

FIG. 5 illustrates a schematic view of the method 500, in accordance with at least one example of this disclosure. The method 500 can be a method of manufacturing an electronic device including a porous polymer dielectric layer on a core. More specific examples of the method 500 are discussed below. The steps or operations of the method 500 are illustrated in a particular order for convenience and clarity; many of the discussed operations can be performed in a different sequence or in parallel without materially impacting other operations. The method 500 as discussed includes operations performed by multiple different actors, devices, and/or systems. It is understood that subsets of the operations discussed in the method 500 can be attributable to a single actor, device, or system could be considered a separate standalone process or method.

At operation 505, the method 500 can include synthesizing a polymer for use as a dielectric layer on a substrate by mixing a dissolute organic solid in a solvent and a solution of a monomer.

At operation 510, the method 500 can include coating the polymer onto the substrate and curing the polymer on the substrate in a chamber of a furnace by heating the polymer and the substrate, cooling the polymer of the substrate slowly within the chamber to slowly cool the polymer, and form porosities in the polymer to create a porous polymer coating on the substrate.

At operation 515, the method 500 can include laser via formation in the cured polymer layer. In examples, the laser can be any laser configured to cut polymers. In another example, the vias can be machined or formed using any other tool that can remove polymer to form the vias. In examples, the formed vias can be cleaned to prepare the formed vias to receive metal or another layer of polymer. For example, a dry desmear process can be used for via cleaning. Additionally, a plasma treatment can be applied to a surface (e.g., the interposer or the porous polymer layer) to help promote copper adhesion within the vias and horizontal routings.

At operation 520, the method 500 can include creating horizontal routings of the vias with metallization of the vias formed using the laser.

At operation 525, the method 500 can include coating another layer of polymer over the metallized vias and following operation 510 to form porosities in the additional polymer layer. In examples, the electronic device 100 can continue to be built up by repeating the steps provided above and laser drilling new vias, filling the vias with metal, and adding subsequent layers of porous polymer layers. In examples, layers of traditional BU dielectric layers can be interwoven between the porous polymer layers.

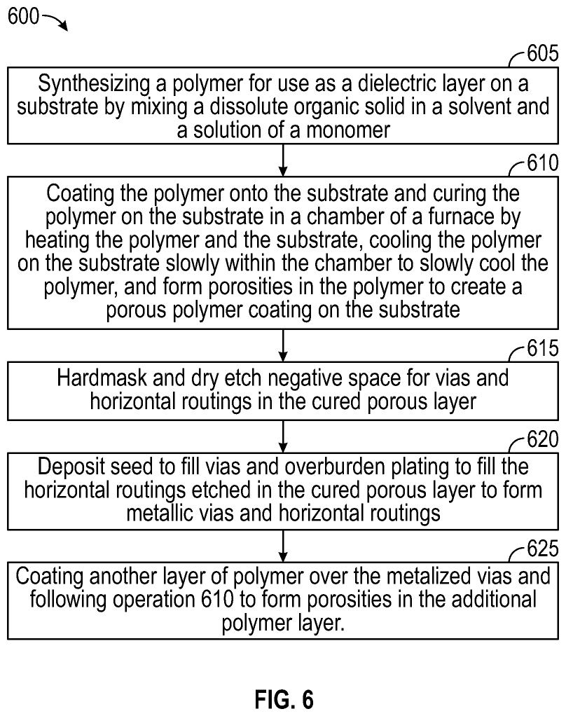

FIG. 6 illustrates a schematic view of the method 600, in accordance with at least one example of this disclosure. The method 600 can be a method of manufacturing an electronic device including a porous polymer dielectric layer on a core. More specific examples of the method 600 are discussed below. The steps or operations of the method 600 are illustrated in a particular order for convenience and clarity; many of the discussed operations can be performed in a different sequence or in parallel without materially impacting other operations. The method 600 as discussed includes operations performed by multiple different actors, devices, and/or systems. It is understood that subsets of the operations discussed in the method 600 can be attributable to a single actor, device, or system that could be considered a separate standalone process or method.

At operation 605, the method 600 can include synthesizing a polymer for use as a dielectric layer on a substrate by mixing a dissolute organic solid in a solvent and a solution of a monomer.

At operation 610, the method 600 can include coating the polymer onto the substrate and curing the polymer on the substrate in a chamber of a furnace by heating the polymer and the substrate, cooling the polymer on the substrate slowly within the chamber to slowly cool the polymer, and form porosities in the polymer to create a porous polymer coating on the substrate.

At operation 615, the method 600 can include hard masking and dry etching negative space for vias and horizontal routings in the cured porous layers. The hard mask and dry etching create a negative pattern for vias and traces. Subsequently, the vias, traces, and surface of the interposer or the porous polymer layer can be plasma treated to promote copper adhesion.

At operation 620, the method 600 can include depositing seeds to fill vias and overburden plating to fill the horizontal routings etched in the cured porous layer to form metallic vias and horizontal routings. The overburdened metal can be removed using a copper chemical mechanical polishing (CMP).

At operation 625, the method 600 can include coating another layer of polymer over the metalized and following, operation 610 to form porosities in the additional polymer layer. As discussed above, these operations can be completed to build an electronic device that matches the design requirements. For example, the vias and the horizontal routings can be altered with each layer of porous polymer or BU dielectric polymer layer on the substrate.

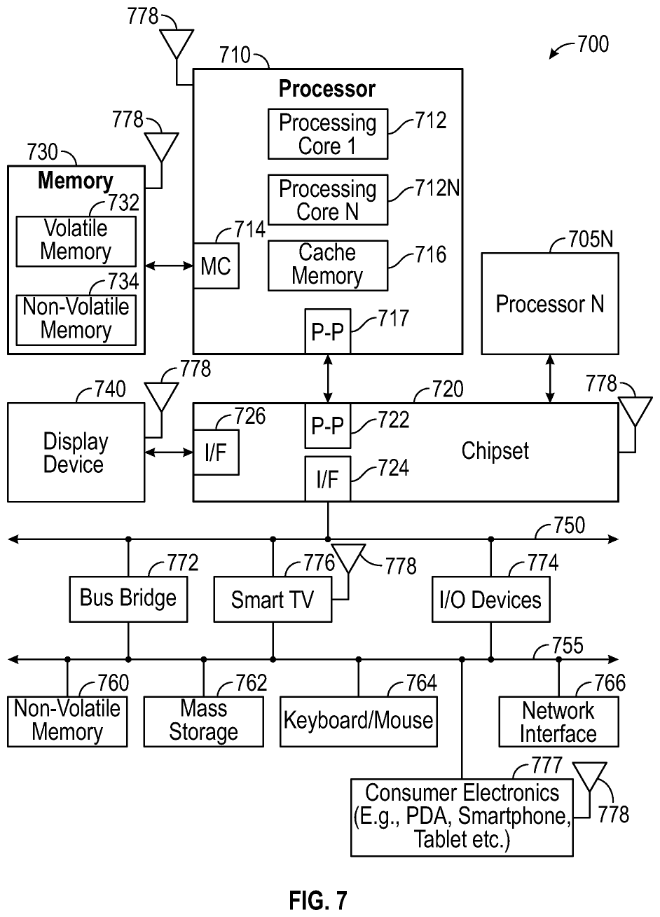

FIG. 7 illustrates a system-level diagram, depicting an example of an electronic device (e.g., system) that may include an electronic device with a porous polymer dielectric layer on a core and/or methods described above. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smartphone, an Internet appliance or any other type of computing device. In some embodiments, system 700 includes a system on a chip (SOC) system.

In one embodiment, processor 710 has one or more processor cores 712 and 712N, where 712N represents the Nth processor core inside processor 710 where N is a positive integer. In one embodiment, system 700 includes multiple processors, including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions, and the like. In some embodiments, processor 710 has a cache memory 716 to cache instructions and/or data for system 700. Cache memory 716 may be organized into a hierarchal structure, including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random-access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals. In one example, any combination of components in a chipset may be separated by a continuous flexible shield as described in the present disclosure.

Chipset 720 connects to display device 740 via interface 726. Display 740 may be, for example, a liquid crystal display (LCD), a light-emitting diode (LED) array, an organic light-emitting diode (OLED) array, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid-state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

To better illustrate the method and apparatuses disclosed herein, a non-limiting list of embodiments is provided here:

Example 1 is an electronic device comprising: an interposer including a metallic through via extending from a first surface of the interposer to a second surface of the interposer; a first porous polymer layer adjacent to the first surface of the interposer; and one or more dies coupled to the first porous polymer layer and electronically connected to the metallic through via.

In Example 2, the subject matter of Example 1 optionally includes wherein the interposer is glass.

In Example 3, the subject matter of any one or more of Examples 1-2 optionally include wherein the interposer is silicon.

In Example 4, the subject matter of any one or more of Examples 1-3 optionally include a second porous polymer layer adjacent to the second surface of the interposer.

In Example 5, the subject matter of any one or more of Examples 1-4 optionally include one or more first horizontal metallic routings interproximal the first surface of the interposer and the first porous polymer layer.

In Example 6, the subject matter of any one or more of Examples 4-5 optionally include one or more first horizontal metallic routings interproximal the first surface of the interposer and the first porous polymer layer; and one or more second horizontal metallic routings interproximal the second surface of the interposer and the second porous polymer layer.

In Example 7, the subject matter of any one or more of Examples 4-6 optionally include a third porous polymer layer adjacent to the first porous polymer layer adjacent to the first surface of the interposer; and one or more first horizontal metallic routings interproximal the first porous polymer layer adjacent to the first surface of the interposer and the third porous polymer layer.

In Example 8, the subject matter of any one or more of Examples 4-7 optionally include a fourth porous polymer layer adjacent the second porous polymer layer; and one or more second horizontal metallic routings interproximal the second porous polymer layer and the fourth porous polymer layer.

In Example 9, the subject matter of any one or more of Examples 1-8 optionally include wherein the first porous polymer layer comprises a nanopolymer.

In Example 10, the subject matter of any one or more of Examples 4-9 optionally include wherein the first porous polymer layer comprises a nanopolymer, and wherein the second porous polymer layer comprises a nanopolymer.

Example 11 is an electronic device, comprising: a cored substrate including a glass core and one or more build up layers on either major surface of the glass core, wherein the one or more build up layers includes at least one porous polymer layer; one or more metallic vias extending through the cored substrate; and one or more dies coupled to the at least one porous polymer layer and electronically connected to the one or more metallic vias.

In Example 12, the subject matter of Example 11 optionally includes a first layer of the one or more build up layers, the first layer adjacent the glass core; and one or more first horizontal metallic routings interproximal the glass core and the first layer.

In Example 13, the subject matter of Example 12 optionally includes wherein the first layer is a porous polymer layer.

In Example 14, the subject matter of Example 13 optionally includes wherein the first layer comprises a nanopolymer.

In Example 15, the subject matter of any one or more of Examples 11-14 optionally include a first layer of the one or more build up layers, the first layer adjacent the glass core; and an adhesion promotion layer interproximal the first layer and the glass core.

In Example 16, the subject matter of Example 15 optionally includes one or more first horizontal metallic routings interproximal the adhesion promotion layer and the first layer.

Example 17 is a computing system, comprising: a device housing; an electronic device within the device housing, the electronic device including: an interposer including a metallic through via extending from a first surface of the interposer to a second surface of the interposer; a first porous polymer layer adjacent to the first surface of the interposer; and one or more dies coupled to the first Porous polymer layer and electronically connected to the metallic through via; and one or more memory dies coupled to the electronic device.

In Example 18, the subject matter of Example 17 optionally includes wherein the interposer is glass.

In Example 19, the subject matter of any one or more of Examples 17-18 optionally include wherein the interposer is silicon.

In Example 20, the subject matter of Example 19 optionally includes wherein the electronic device further comprises one or more first horizontal metallic routings interproximal the first surface of the interposer and the first porous polymer layer.

Example 21 is a method of making an electronic device comprising: synthesizing a polymer for use as a dielectric layer on a substrate by mixing a dissolute organic solid in a solvent and a solution of a monomer; coating the polymer onto the substrate; curing the polymer on the substrate in a chamber of a furnace by heating the polymer and the substrate; and cooling the polymer on the substrate slowly within the chamber to slowly cool the polymer and generate porosities in the polymer to create a porous polymer coating on the substrate.

In Example 22, the subject matter of Example 21 optionally includes wherein the polymer on the substrate is cured between three hundred and sixty and four hundred degrees Celsius.

In Example 23, the subject matter of any one or more of Examples 21-22 can optionally include wherein the polymer is slit coat onto the substrate.

In Example 24, the subject matter of any one or more of Examples 21-23 can optionally include wherein the polymer is spin-coated onto the substrate.

Example 25 is a system, device, or method, including the subject matter of any one or more of examples 1-24.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device comprising:
an interposer including a metallic through via extending from a first surface of the interposer to a second surface of the interposer;
a first porous polymer layer adjacent to the first surface of the interposer; and
one or more dies connected to the metallic through via.

2. The electronic device of claim 1, wherein the interposer includes glass.

3. The electronic device of claim 1, wherein the interposer includes silicon.

4. The electronic device of claim 1, further comprising a second porous polymer layer adjacent to the second surface of the interposer.

5. The electronic device of claim 1, further comprising one or more first horizontal metallic routings interproximal the first surface of the interposer and the first porous polymer layer.

6. The electronic device of claim 4, further comprising:
one or more first horizontal metallic routings interproximal the first surface of the interposer and the first porous polymer layer; and
one or more second horizontal metallic routings interproximal the second surface of the interposer and the second porous polymer layer.

7. The electronic device of claim 4, further comprising:
a third porous polymer layer adjacent to the first porous polymer layer adjacent to the first surface of the interposer; and
one or more first horizontal metallic routings interproximal the first porous polymer layer adjacent to the first surface of the interposer and the third porous polymer layer.

8. The electronic device of claim 4, further comprising:
a fourth porous polymer layer adjacent the second porous polymer layer; and
one or more second horizontal metallic routings interproximal the second porous polymer layer and the fourth porous polymer layer.

9. The electronic device of claim 1, wherein the first porous polymer layer comprises a nanopolymer.

10. The electronic device of claim 4, wherein the first porous polymer layer comprises a nanopolymer, and wherein the second porous polymer layer comprises a nanopolymer.

11. An electronic device, comprising:
a cored substrate including a glass core and one or more build up layers on either major surface of the glass core, wherein the one or more build up layers includes at least one porous polymer layer;
one or more metallic vias extending through the cored substrate; and
one or more dies coupled to the at least one porous polymer layer and connected to the one or more metallic vias.

12. The electronic device of claim 11, further comprising:
a first layer of the one or more build up layers, the first layer adjacent the glass core; and
one or more first horizontal metallic routings interproximal the glass core and the first layer.

13. The electronic device of claim 12, wherein the first layer is a porous polymer layer.

14. The electronic device of claim 13, wherein the first layer comprises a nanopolymer.

15. The electronic device of claim 11, further comprising:
a first layer of the one or more build up layers, the first layer adjacent the glass core; and
an adhesion promotion layer interproximal the first layer and the glass core.

16. The electronic device of claim 15, further comprising:
one or more first horizontal metallic routings interproximal the adhesion promotion layer and the first layer.

17. A method of making an electronic device comprising:
coating a polymer onto the substrate, the polymer synthesized for use as a dielectric layer by mixing a dissolute organic solid in a solvent and a solution of a monomer;
curing the polymer on the substrate by heating the polymer and the substrate; and
cooling the polymer on the substrate slowly to generate porosities in the polymer to create a porous polymer coating on the substrate.

18. The method of claim 17, wherein the polymer on the substrate is cured in a chamber of a furnace between three hundred and sixty and four hundred degrees Celsius, and wherein the polymer on the substrate is cooled within the chamber to slowly cool the polymer.

19. The method of claim 17, wherein the polymer is slit coated onto the substrate.

20. The method of claim 17, wherein the polymer is spin-coated onto the substrate.
